(19) United States
(12) Patent Application Publication
(10) Pub. No.: US 2021/0072862 A1
(43) Pub. Date: Mar. 11, 2021

(54) TOUCH INPUT DEVICE COMPRISING STRAIN GAUGE

(71) Applicant: HiDeep Inc., Seongnam-si, Gyeonggi-do (KR)

(72) Inventors: In Uk JEONG, Seongnam-si, Gyeonggi-do (KR); Gi Duk KIM, Seongnam-si, Gyeonggi-do (KR); Hyoung Wook WOO, Seongnam-si, Gyeonggi-do (KR); Tae Hoon KIM, Seongnam-si, Gyeonggi-do (KR); Bong Jin SEO, Seongnam-si, Gyeonggi-do (KR)

(73) Assignee: HiDeep Inc., Seongnam-si, Gyeonggi-do (KR)

(21) Appl. No.: 16/644,806

(22) PCT Filed: Sep. 4, 2018
(86) PCT No.: PCT/KR2018/010313

§ 371 Date: Mar. 5, 2020

(30) Foreign Application Priority Data
Sep. 6, 2017 (KR) 10-2017-0113714

(51) Int. Cl. G06F 3/044

(52) U.S. Cl. CPC G06F 3/0443; H01L 27/323; G06F 2203/04105

(57) ABSTRACT

A touch input device capable of detecting touch pressure according to an embodiment of the present invention includes a display module and a pressure sensor layer disposed on a lower portion of the display module, wherein an adhesive layer is present between the display module and the pressure sensor layer to adhere the pressure sensor layer to the display module, and the pressure sensor layer includes a structure in which a first strain gauge is formed on an upper surface of a substrate and a second strain gauge is formed on a lower surface of the substrate. When pressure is applied to the display module, the display module is bent, the electrical properties of each of the first strain gauge and the second strain gauge are changed as the display module is bent, and the Young's Modulus of the substrate is greater than the Young's Modulus of the adhesive layer.

### TECHNICAL FIELD

The present invention relates to a touch input device having a pressure sensor layer on which a strain gauge is formed is disposed on a lower portion of a display module, and specifically, to a touch input device capable of improving detection sensitivity to touch pressure.

### BACKGROUND ART

Various kinds of input devices are used for the operation of a computing system. For example, input devices such as buttons, keys, joysticks, and touch screens are used. Due to the easy and simple operation of a touch screen, the use of the touch screen is increasing in the operation of the computing system.

The touch screen may constitute a touch surface of a touch input device including a touch sensor panel, which may be a transparent panel provided with a touch-sensitive surface. Such a touch sensor panel may be attached to the front surface of a display screen so that the touch-sensitive surface may cover a visible surface of the display screen. By simply touching the touch screen by means of a finger or the like, a user may operate the computing system. In general, the computing system recognizes a touch and a touch position on the touch screen and interprets the touch to perform a calculation accordingly.

At this time, there is a need for a touch input device capable of detecting the force magnitude of a touch as well as the position of the touch according to the touch on the touch screen without deteriorating the performance of a display module. As a sensor for detecting the force magnitude of a touch, a pressure sensor layer including a strain gauge may be used. At this time, a demand for a touch input device capable of improving detection sensitivity to touch pressure is increasing.

### DISCLOSURE OF THE INVENTION

### Technical Problem

The purpose of the present invention is to improve the touch pressure detection strength of a touch input device by embodying the relationship between the Young's Modulus of a substrate of a pressure sensor layer including a strain gauge and the Young's Modulus of an adhesive layer when the pressure sensor layer capable of detecting touch pressure is used in a touch input device.

### Technical Solution

A touch input device according to an embodiment of the present invention is a touch input device capable of detecting touch pressure which includes a display module and a pressure sensor layer disposed on a lower portion of the display module, wherein an adhesive layer is present between the display module and the pressure sensor layer to adhere the pressure sensor layer to the display module, and the pressure sensor layer includes a structure in which a first strain gauge is formed on an upper surface of a substrate and a second strain gauge is formed on a lower surface of the substrate. When pressure is applied to the display module, the display module is bent, the electrical properties of each of the first strain gauge and the second strain gauge are changed as the display module is bent, and the Young's Modulus of the substrate is greater than the Young's Modulus of the adhesive layer.

Here, the Young's Modulus of the substrate may be less than 500 GPa.

Here, the first strain gauge and the second strain gauge may be formed at positions corresponding to each other on the opposite sides of the substrate.

Here, the first strain gauge may be formed in plurality on an upper surface of the substrate and the second strain gauge may be formed in plurality on a lower surface of the substrate.

Here, the first strain gauge and the second strain gauge formed at positions corresponding to each other of the substrate may be electrically connected.

A touch input device according to an embodiment of the present invention is a touch input device capable of detecting touch pressure which includes a display module and a pressure sensor layer disposed on a lower portion of the display module and including a substrate, a first strain gauge formed on an upper surface of the substrate and a second strain gauge formed on a lower surface of the substrate, a first adhesive layer formed between the display module and the pressure sensor layer to adhere the display module and the pressure sensor layer, and a second adhesive layer formed between the pressure sensor layer and the material layer for substrate reinforcement to adhere the pressure sensor layer and the material layer for substrate reinforcement, wherein when pressure is applied to the display module, the display module is bent, the electrical properties of each of the first strain gauge and the second strain gauge are changed as the display module is bent, and the Young's Modulus of the substrate is greater than the Young's Modulus of the first adhesive layer and the Young's Modulus of the second adhesive layer.

Here, the Young's Modulus of the substrate may be less than 500 GPa.

Here, the first adhesive layer and the second adhesive layer may be formed of the same material.

Here, the Young's Modulus of the first adhesive layer may be less than the Young's Modulus of the second adhesive layer.

Here, the first strain gauge and the second strain gauge may be formed at positions corresponding to each other on the opposite sides of the substrate.

Here, the first strain gauge may be formed in plurality on an upper surface of the substrate and the second strain gauge may be formed in plurality on a lower surface of the substrate.

Here, the first strain gauge and the second strain gauge formed at positions corresponding to each other of the substrate may be electrically connected.

### Advantageous Effects

According to a touch input device using a pressure sensor layer including a strain gauge according to the above configuration, the detection sensitivity to touch pressure may be improved.

Also, there is an advantage in that it is advantageous to ensure the orientation of each strain gauge formed on the opposite sides of a substrate of the pressure sensor layer.

### BRIEF DESCRIPTION OF THE DRAWINGS

FIG. 1a and FIG. 1b are schematic views of a capacitive touch sensor included in a touch input device according to the present invention and a configuration for the operation thereof;

FIG. 2 illustrates a control block for controlling a touch position, a touch force, and a display operation in a touch input device according to the present invention;

FIG. 3a and FIG. 3b are conceptual views for describing the configuration of a display module in a touch input device according to the present invention;

FIG. 4a is a cross-sectional view schematically illustrating a portion of a touch input device according to an embodiment of the present invention;

FIG. 4b to FIG. 4e illustrate an example in which a strain gauge is applied in a touch input device according to the present invention;

FIG. 5a and FIG. 5d to FIG. 5f are plan views of an exemplary force sensor capable of sensing touch pressure used in a touch input device according to the present invention;

FIG. 5b and FIG. 5c illustrate an exemplary strain gauge which may be applied to a touch input device according to the present invention;

FIG. 6a to FIG. 6f are graphs showing simulation results for describing a touch input device according to the present invention;

FIG. 7a to FIG. 7e are graphs showing simulation results for describing a touch input device according to the present invention;

FIG. 8a to FIG. 8c are graphs showing simulation results for describing a touch input device according to the present invention;

FIG. 9a to FIG. 9c are graphs showing simulation results for describing a touch input device according to the present invention;

FIG. 10 is a cross-sectional view schematically illustrating a portion of a touch input device according to another embodiment of the present invention;

FIG. 11 to FIG. 18 are graphs showing simulation results for describing a touch input device according to the present invention; and

FIG. 19a to FIG. 19d are views illustrating the shape of an electrode included in a touch input device according to the present invention.

### MODE FOR CARRYING OUT THE INVENTION

The present invention will be described in detail with reference to the accompanying drawings, which illustrate specific embodiments in which the invention may be practiced. The specific embodiments shown in the accompanying drawings will be described in detail enough to enable those skilled in the art to which the present invention belongs to practice the invention. Embodiments other than the specific embodiments are different from one another but do not need to be mutually exclusive. Furthermore, it is to be understood that the following detailed description is not intended to be taken in a limited sense.

The detailed description of the specific embodiments shown in the accompanying drawings is read in connection with the accompanying drawings, wherein the drawings are considered as part of the entire description of the invention. Reference to directions or orientations is for convenience of description only and is not intended to limit the scope of the invention in any way.

Specifically, a term indicating a position such as “down, up, horizontal, vertical, top, bottom, up, down, top, bottom,” or a derivative thereof (for example, “horizontally, downward, upward” and the like) should be understood with reference to both the drawings being described and related descriptions. In particular, such relative words are merely for convenience of description, and do not require a device of the present invention to be configured or operated in a particular direction.

Also, a term indicating the inter-bonding relationship between components, such as “mounted, attached, connected, linked, and interconnected,” may mean, unless otherwise indicated, a state in which individual components are attached, connected, or fixed directly or indirectly, and it should be understood as being a term encompassing not only a movable attached, connected, or fixed state but also a non-movable state.

A touch input device according to the present invention may be used in portable electronic products such as smart phones, smart watches, tablet PCs, notebook computers, personal digital assistants (PDA), MP3 players, cameras, camcorders, electronic dictionaries and in home appliances such home PCs, TVs, DVDs, refrigerators, air conditioners, and microwave ovens. In addition, the touch input device capable of detecting the touch pressure including a display module according to the present invention may be used without limitation in all products requiring an apparatus for display and input, such as industrial control devices and medical devices.

Hereinafter, a touch input device capable of detecting touch pressure according to an embodiment of the present invention will be described with reference to the accompanying drawings. Before describing a driving principle for touch pressure detection in the touch input device of the present invention, a driving principle for detecting a touch position will be described, first. Here, a capacitive touch sensor 10 for detecting a touch position is illustrated, but a touch sensor 10 capable of detecting a touch position in any manner may be applied in the present invention.

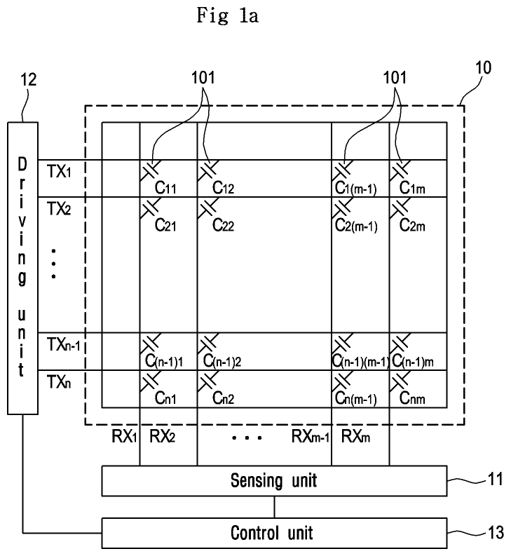

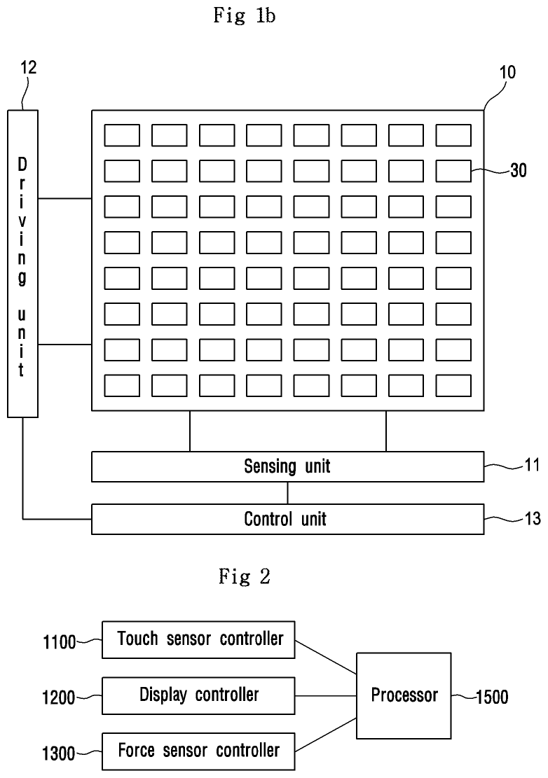

FIG. 1a is a schematic view of the capacitive touch sensor 10 included in a touch input device according to the present invention and a configuration for the operation thereof.

Referring to FIG. 1a, the touch sensor 10 includes a plurality of driving electrodes TX1 to TXn, a plurality of receiving electrodes RX1 to RXm, a driving unit 12 applying a driving signal to the plurality of driving electrodes TX1 to TXn for the operation of the touch sensor 10, and a sensing unit 11 receiving a sensing signal including information on the capacitance change amount which is changed according to a touch on a touch surface from the plurality of receiving electrodes RX1 to RXm to detect a touch and a touch position.

As illustrated in FIG. 1a, the touch sensor 10 may include the plurality of driving electrodes TX1 to TXn and the plurality of receiving electrodes RX1 to RXm. In FIG. 1a, the plurality of driving electrodes TX1 to TXn and the plurality of receiving electrodes RX1 to RXm are illustrated as configuring an orthogonal array, but the present invention is not limited thereto. The plurality of driving electrodes TX1 to TXn and the plurality of receiving electrodes RX1 to RXm may have any number of dimensions and an application arrangement thereof, including diagonal, concentric, and three-dimensional random arrays. Here, n and m are positive integers and may have the same or different values, and the size thereof may vary according to an embodiment.

Each of the plurality of driving electrodes TX1 to TXn and each of the plurality of receiving electrodes RX1 to RXm may be arranged to cross each other. A driving electrode TX may include the plurality of driving electrodes TX1 to TXn extended in a first axis direction and a receiving electrode RX may include the plurality of receiving electrodes RX1 to RXm extended in a second axis direction intersecting the first axis direction.

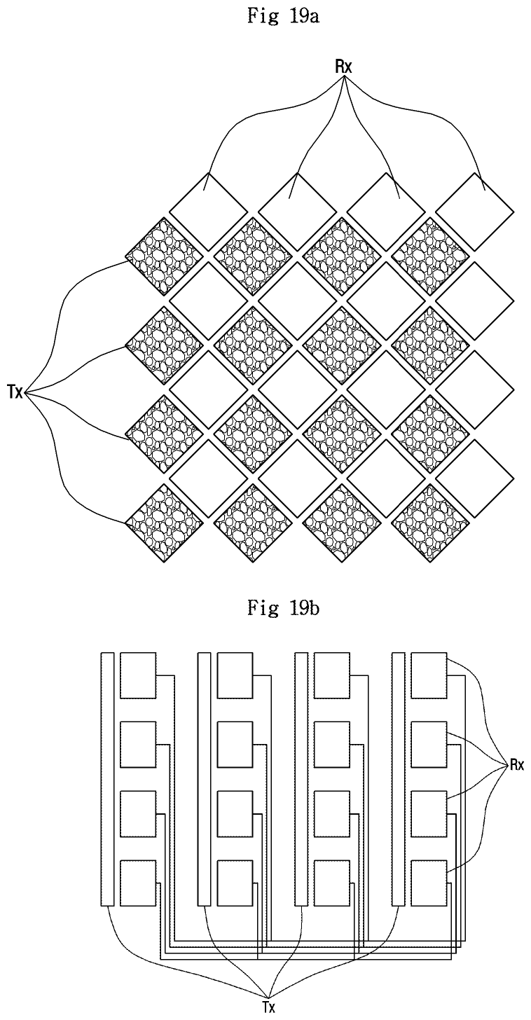

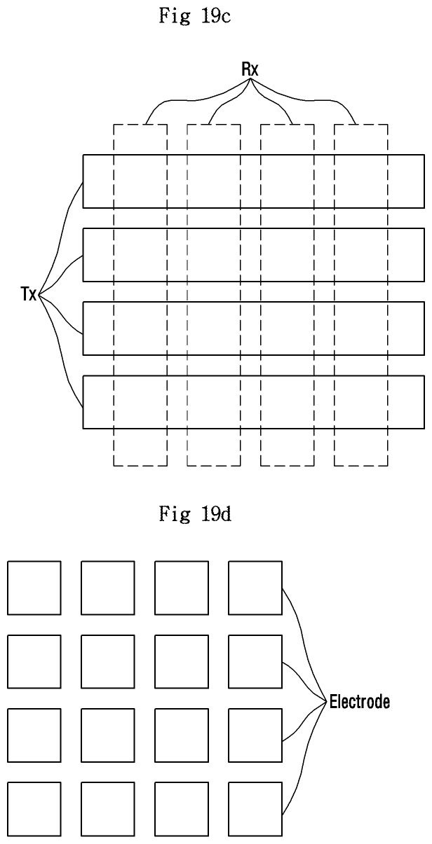

As illustrated in FIG. 19a and FIG. 19b, in the touch sensor 10 according to an embodiment of the present invention, the plurality of driving electrodes TX1 to TXn and the plurality of receiving electrodes RX1 to RXm may be formed on the same layer. For example, the plurality of driving electrodes TX1 to TXn and the plurality of receiving electrodes RX1 to RXm may be formed on an upper surface of a display panel 200A to be described later.

Also, as illustrated in FIG. 19a, the plurality of driving electrodes TX1 to TXn and the plurality of receiving electrodes RX1 to RXm may be formed on different layers. For example, any one of the plurality of driving electrodes TX1 to TXn and the plurality of receiving electrodes RX1 to RXm is formed on an upper surface of the display panel 200A, and the other thereof may be formed on a lower surface of a glass layer 200B to be described layer or inside the display panel 200A.

The plurality of driving electrodes TX1 to TXn and the plurality of receiving electrodes RX1 to RXm may be formed of a transparent conductive material (for example, indium tin oxide (ITO) or antimony tin oxide (ATO) made of tin oxide (SnO₂), indium oxide (In₂O₃), and the like). However, this is only exemplary. The driving electrode TX and the receiving electrode RX may be formed of another conductive material or an opaque conductive material. For example the driving electrode TX and the receiving electrode RX may be configured to include at least one of silver ink, copper, nano silver, or a carbon nanotube (CNT). In addition, the driving electrode TX and the receiving electrode RX may be implemented as a metal mesh.

The driving unit 12 according to an embodiment of the present invention may apply a driving signal to the driving electrodes TX1 to TXn. In an embodiment of the present invention, the driving signal may be sequentially applied to one driving electrode at a time from a first driving electrode TX1 to an nth driving electrode TXn. The application of the driving signal may be repeatedly performed. However, this is merely exemplary. The driving signal may be simultaneously applied to multiple driving electrode according to an embodiment.

The sensing unit 11 may detect a touch and a touch position by receiving a sensing signal including information on capacitance Cm: 101 generated between the driving electrodes TX1 to TXn to which the driving signal is applied through the receiving electrodes RX1 to RXm and the receiving electrodes RX1 to RXm. For example, the sensing signal may be a signal in which the driving signal applied to the driving electrode TX is coupled by the capacitance Cm:101 generated between the driving electrode TX and the receiving electrode RX. As described above, a process of sensing the driving signals applied from the first driving electrode TX1 to the nth driving electrode TXn through the receiving electrodes RX1 to RXm may be referred to as scanning the touch sensor 10.

For example, the sensing unit 11 may be configured to include a receiver (not shown) connected to each of the receiving electrodes RX1 to RXm through a switch. The switch is turned on in a time interval for sensing a signal of the receiving electrode RX so that a sensing signal from the receiving electrode RX may be sensed at the receiver. The receiver may be configured to include an amplifier (not shown) and a feedback capacitor coupled between a negative(−) input terminal of the amplifier and an output terminal of the amplifier, that is, a feedback path. At this time, a positive(+) input terminal of the amplifier may be connected to a ground. In addition, the receiver may further include a reset switch connected in parallel with the feedback capacitor. The reset switch may reset the conversion from a current to a voltage performed by the receiver. The negative input terminal of the amplifier is connected to a corresponding receiving electrode RX to receive and then integrate a current signal including information on the capacitance Cm:101 to convert the current signal to a voltage. The sensing unit 11 may further include an analog to digital converter (not shown) for converting data integrated through the receiver into digital data. Subsequently, the digital data may be input to a processor (not shown) to be processed to obtain touch information on the touch sensor 10. The sensing unit may be configured to include the ADC and the processor in addition to the receiver.

A control unit 13 may perform a function of controlling the operation of the driving unit 12 and the sensing unit 11. For example, the control unit 13 generates a driving control signal and transmits the same to the driving unit 12 so that a driving signal is applied to the driving electrode TX preset at a predetermined time. In addition, the control unit 13 generates a sensing control signal and transmits the same to the sensing unit 11 so that the sensing unit 11 receives a sensing signal from the receiving electrode RX preset at a predetermined time to perform a preset function.

In FIG. 1a, the driving unit 12 and the sensing unit may constitute a touch detection device (not shown) capable of detecting a touch and a touch position on the touch sensor 10. The touch detection device may further include the control unit 13. The touch detection device may be implemented by being integrated on a touch sensing Integrated Circuit (IC), which is a touch sensing circuit in a touch input device including the touch sensor 10. The driving electrode TX and the receiving electrode RX included in the touch sensor 10 may be connected to the driving unit 12 and the sensing unit 11 included in the touch sensing IC through, for example, a conductive trace and/or a conductive pattern printed on a circuit board. The touch sensing IC may be located on the circuit board on which the conductive pattern is printed. According to an embodiment, the touch sensing IC may be mounted on a main board for the operation of the touch input device.

As described above, a capacitance Cm of a predetermined value is generated at each intersection point of the driving electrode TX and the receiving electrode RX, and the value of the capacitance may change when an object, such as a finger, approaches the touch sensor 10. in FIG. 1a, the capacitance may represent a mutual capacitance Cm. Such electrical properties may be sensed at the sensing unit 11 to sense a touch and/or a touch position on the touch sensor 10. For example, a touch and and/or a touch position on a surface of the touch sensor 10, the surface formed of a two-dimensional plane formed of a first axis and a second axis, may be sensed.

More specifically, when a touch occurs on the touch sensor 10, the position of the touch in the second axis direction may be detected by detecting the driving electrode TX to which a driving signal is applied. Similarly, the position of the touch in the first axis direction may be detected by detecting the capacitance change from a received signal received through the receiving electrode RX when the touch occurred on the touch sensor 10.

In the above, an operation method of the touch sensor which senses a touch position based on a mutual capacitance change amount between the driving electrode TX and the receiving electrode RX has been described, but the present invention is not limited thereto. That is, as shown in FIG. 1b, it is possible to sense the touch position based on a self capacitance change amount.

FIG. 1b is a schematic view illustrating another capacitive touch sensor 10 included in a touch input device according to another embodiment of the present invention, and an operation thereof.

The touch sensor 10 illustrated in FIG. 1b is provided with a plurality of touch electrodes 30. The plurality of touch electrodes 30 may be disposed in a lattice shape with predetermined intervals as illustrated in FIG. 19d, but are not limited thereto.

The driving control signal generated by the control unit 130 is transferred to the driving unit 12, and the driving unit 12 applies a driving signal to the touch electrode 30 preset at a predetermined time based on the driving control signal. In addition, the sensing control signal generated by the control unit 13 is transferred to the sensing unit 11, and the sensing unit receives a sensing signal from the touch electrode 30 preset at a predetermined time based on the sensing control signal. At this time, the sensing signal may be a signal for the self capacitance change amount formed on the touch electrode 30.

At this time, a touch and/or a touch location of the touch sensor 10 is detected by the sensing signal sensed by the sensing unit 11. For example, since the coordinates of the touch electrode 30 are already known, a touch and/or a touch location of an object on the surface of the touch sensor 10 may be sensed.

In the above description, for convenience, the driving unit 12 and the sensing unit 11 have been described as being divided into separate blocks and operating. However, it is also possible to perform an operation in which a driving signal is applied to the touch electrode 30 and a sensing signal is received from the touch electrode 30 in one driving and sensing unit.

Although a capacitive touch sensor panel has been described in detail as the touch sensor 10 above, the touch sensor 10 for detecting a touch and a touch location in a touch input device 1000 according to an embodiment of the present invention may be implemented using any touch sensing method, such as a surface capacitance method, a projected capacitance method, a resistive film method, a surface acoustic wave (SAW) method, an infrared method, an optical imaging method, a dispersive signal technology method, and an acoustic pulse recognition method.

FIG. 2 illustrates a control block for controlling a touch position, a touch force, and a display operation in a touch input device according to the present invention.

In he ouch input device 1000 configured to detect a touch force (touch pressure) in addition to a display function and touch position detection, a control block may be configured to include a touch sensor controller 1100 for detecting the touch position described above, a display controller 1200 for driving a display panel, and a force sensor controller 1300 for detecting a force. The display controller 1200 may include a control circuit for displaying desired contents on a display panel 200A by receiving an input from a central processing unit (CPU), an application processor (AP), or the like, which is a central processing unit on a main board for the operation of the touch input device 1000. The control circuit may include a display panel control IC, a graphic control IC, and other circuits required for the operation of the display panel 200A.

The force sensor controller 1300 for detecting a force through a force sensor is configured similar to the configuration of the touch sensor controller 1100 to operate similarly to the touch sensor controller 1100.

According to an embodiment, the touch sensor controller 1100, the display controller 1200, and the force sensor controller 1300 may be included in the touch input device 1000 as different components. For example, the touch sensor controller 1100, the display controller 1200, and the force sensor controller 1300 may each be composed of different chips. At this time, a processor 1500 of the touch input device 1000 may function as a host processor for the touch sensor controller 1100, the display controller 1200, and the force sensor controller 1300.

The touch input device 1000 according to an embodiment of the present invention may include an electronic device having a display screen and/or a touch screen, the electronic device being a cell phone, a Personal Data Assistant (PDA), a smart phone, a tablet Personal Computer (PC), an MP3 player, a notebook computer, and the like.

In order to manufacture the touch input device 1000 as being thin and light weight, the touch sensor controller 1100, the display controller 1200, and the force sensor controller 1300, which are separately configured as described above, may be integrated into one or more configurations according to an embodiment. In addition, it is also possible for each of the controllers to be integrated into the processor 1500. In addition, the touch sensor 10 and/or the force sensor may be integrated in the display panel 200A according to an embodiment.

In the touch input device 1000 according to an embodiment, the touch sensor 10 for detecting a touch position may be located outside or inside the display panel 200A. The display panel 200A of the touch input device 1000 according to an embodiment may be a display panel included in a liquid crystal display (LCD), a plasma display panel (PDP), an organic light emitting diode (OLED), and the like. Accordingly, a user may perform a touch on a touch surface while visually confirming a screen displayed on the display panel to perform an input action.

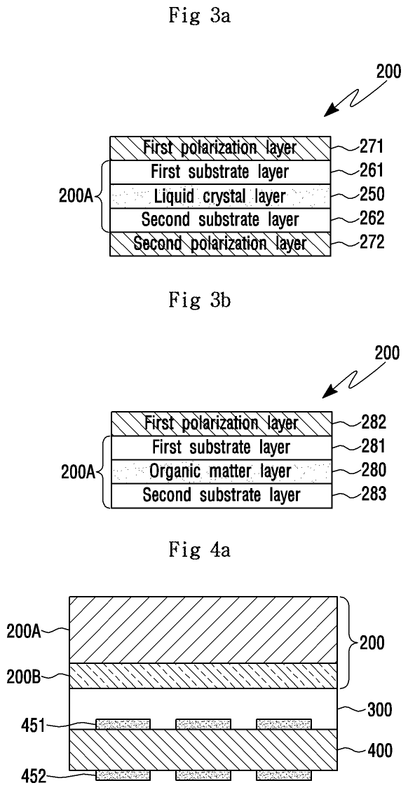

FIG. 3a and FIG. 3b are conceptual views for describing the configuration of a display module 200 in the touch input device 100 according to the present invention.

First, referring to FIG. 3a, the configuration of the display module 200 including the display panel 200A using an LCD panel will be described.

As shown in FIG. 3a, the display module 200 may include the display panel 200A, a first polarization layer 271 disposed on an upper portion of the display panel 200A, and a second polarization layer 272 disposed on a lower portion of the display panel 200A. In addition, the display panel 200A, which is an LCD panel, may include a liquid crystal layer 250 including a liquid crystal cell, a first substrate layer 261 disposed on an upper portion of the liquid crystal layer 250, and a second substrate layer 262 disposed on a lower portion of the liquid crystal layer 250. At this time, the first substrate layer 261 may be a color filter glass, and the second substrate layer 262 may be a TFT glass. In addition, according to an embodiment, at least one of the first substrate layer 261 and the second substrate layer 262 may be formed of a bendable material such as plastic. In FIG. 3a, the second substrate layer 262 may be formed of various layers including a data line, a gate line, TFT, a common electrode Vcom, a pixel electrode, and the like. These electrical components may generate a controlled electric field and operate to orient liquid crystals located in the liquid crystal layer 250.

Next, referring to FIG. 3b, a configuration of the display module 200 including the display panel 200A using an OLED panel will be described.

As shown in FIG. 3b, the display module 200 may include the display panel 200A, which is an OLED panel, and a first polarization layer 282 disposed on an upper portion of the display panel 200A. In addition, the display panel 200A, which is an OLED panel, may include an organic layer 280 including an organic light-emitting diode, a first substrate layer 281 disposed on an upper portion of the organic matter layer 280, and a second substrate layer 283 disposed on a lower portion of the organic matter layer 280. At this time, the first substrate layer 281 may be an encapsulation glass, and the second substrate layer283 may be a TFT glass. In addition, according to an embodiment, at least one of the first substrate layer 281 and the second substrate layer 283 may be formed of a bendable material such as plastic.

The OLED panel illustrated in FIG. 3b may include an electrode used for driving the display panel 200A, such as a gate line, a data line, a first power line ELVDD, and a second power line ELVSS. An organic light-emitting diode panel is a self light-emitting display panel using a principle in which light is generated when electrons and holes are combined in an organic matter layer when a current flows to a fluorescent or phosphorescent organic material thin film, and an organic material constituting a light-emitting layer determines the color of the light.

Specifically, the OLED uses a principle in which an organic matter emits light when the organic matter is applied on glass or plastic to allow electricity to flow. That is, a principle in which when holes and electrons are respectively injected into a positive electrode and a negative electrode of the organic matter to be recombined in the light emitting layer, excitons in a high energy state are formed, and energy is emitted as the excitons are dropped to a low energy state, thereby emitting energy to generate light of a specific wavelength is used. At this time, the color of the light is changed according to the organic matter of the light emitting layer.

According to the operating properties of pixels constituting a pixel matrix, there are Passive-matrix Organic Light-Emitting Diode (PM-OLED) of a line driving method and an Active-matrix Organic Light-Emitting Diode (AM-OLED) of an individual driving method. Since both do not require a backlight, there are advantages in that a display module may be implemented as being very thin, the contrast ratio is constant according to an angle, and the color reproducibility according to a temperature is good. Moreover, non-driving pixels are very economical in that power is not consumed.

In terms of operation, the PM-OLED emits light only during a scanning time with a high current and the AM-OLED continuously maintains a light-emitting state during a frame time with a low current. Therefore, when compared with the PM-OLED, the AM-OLED has advantages in that the resolution thereof is good, large-area display panel driving is advantageous, and power consumption is low. In addition, since a thin film transistor is embedded to individually control each element, it is easy to implement a fine screen.

Also, the organic matter layer 280 may include a hole injection layer (HIL), a hole transfer layer (HTL), an electron injection layer (EIL), an electron transfer layer (ETL), and an emission material layer (EML).

To briefly describe each layer, the HIL injects holes and uses a material such as CuPc. The HTL functions to transfer the injected holes and mainly uses a material having a good hole mobility. As the HTL, arylamine, TPD, and the like may be used. The EIL and the ETL are layers for injecting and transporting electrons, and the injected electrons and holes are combined in an EML to emit light. The EML is a material expressing a color to be emitted, and is composed of a host for determining the lifetime of an organic matter and a dopant for determining color feel and efficiency. This is only to describe the basic configuration of the organic matter layer 280 included in the OLED panel, and the present invention is not limited to the layered structure, material, and the like of the organic matter layer 280.

The organic matter layer 280 is inserted between an anode (not shown) and a cathode (not shown). When the TFT is turned on, a driving current is applied to the anode to inject holes and electrons are injected into the cathode, so that the electrons and the holes are transferred to the organic matter layer 280 to emit light.

It will be apparent to those skilled in the art that the LCD panel or OLED panel may further include other configurations and may be modified in order to perform the display function.

The display module 200 of the touch input device 1000 according to the present invention may include the display panel 200A and a configuration for driving the display panel 200A. Specifically, when the display panel 200A is an LCD panel, the display module 200 may be configured to include a backlight unit (not shown) disposed on a lower portion of the second polarization layer 272, and may further include a display panel control IC, a graphic control IC, and other circuits for the operation of the LCD panel. display panel.

In the touch input device 1000 according to an embodiment of the present invention, the touch sensor 10 for detecting a touch position may be located outside or inside the display module 200.

When the touch sensor 10 is disposed outside the display module 200 in the touch input device 1000, a touch sensor panel may be disposed on an upper portion of the display module 200, and the touch sensor may be included in the touch sensor panel. A touch surface for the touch input device 1000 may be a surface of the touch sensor panel.

When the touch sensor 10 is disposed inside the display module 200 in the touch input device 1000, the touch sensor 10 may be configured to be located outside the display panel 200A. Specifically, the touch sensor 10 may be formed on upper surfaces of the first substrate layers 261 and 281. At this time, the touch surface for the touch input device 1000 is an outer surface of the display module 200, which may be an upper surface or a lower surface in FIG. 3a and FIG. 3b.

When the touch sensor 10 is disposed inside the display module 200 in the touch input device 1000, at least some portions of the touch sensor 10 may be configured to be located in the display panel 200A and at least the other portions of the touch sensor 10 may be configured to be located outside the display panel 200A according to an embodiment. For example, any one electrode of the driving electrode TX and the receiving electrode RX constituting the touch sensor 10 may be configured to be located outside the display panel 200A, and the other electrode may be configured to be located inside the display panel 200A. More specifically, any one electrode of the driving electrode TX and the receiving electrode RX constituting the touch sensor 10 may be formed on upper surfaces of the first substrate layers 261 and 281, and the other electrode thereof may be formed on either lower surfaces of the first substrate layers 261 and 281 or upper surfaces of the second substrate layers 262 and 283.

When the touch sensor 10 is disposed inside the display module 200 in the touch input device 1000, the touch sensor 10 may be configured to be located inside the display panel 200A. Specifically, the touch sensor 10 may be formed on either lower surfaces of the first substrate layers 261 and 281 or upper surfaces of the second substrate layers 262 and 283.

When the touch sensor 10 is disposed inside the display panel 200A, an electrode for the operation of a touch sensor may be further disposed. However, various configurations and/or electrodes located inside the display panel 200A may be used as the touch sensor for touch sensing. Specifically, the display panel 200A is an LCD panel, at least any one of electrodes included in the touch sensor 10 may include at least any one of the data line, the gate line, the TET, the common electrode Vcom, or the pixel electrode, and when the display panel 200A is an OLED panel, at least any one of electrodes included in the touch sensor 10 may include at least any one of the data line, the gate line, the first power line ELVDD, or the second power line EVSS.

At this time, the touch sensor 10 may operate as the driving electrode and the receiving electrode described with reference to FIG. 1a to detect a touch position according to mutual capacitance between the driving electrode and the receiving electrode. In addition, the touch sensor 10 may operate as single electrodes 30 described with reference to FIG. 1b to detect a touch position according to self capacitance of each of the single electrodes 30. At this time, when an electrode included in the touch sensor 10 is an electrode used for driving the display panel 200A, the display panel 200A is driven during a first time interval, and a touch position is detected during a second time interval different from the first time interval.

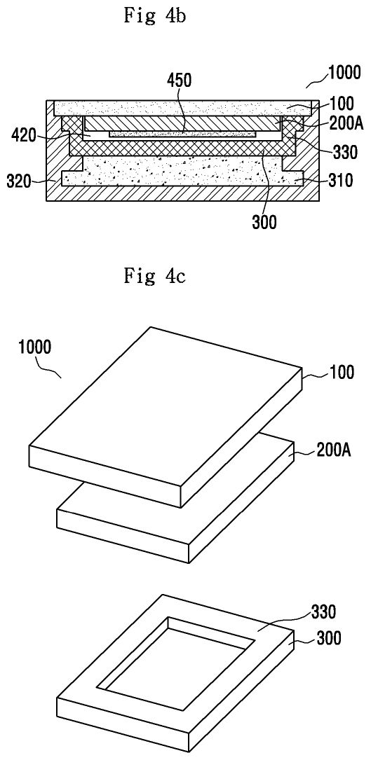

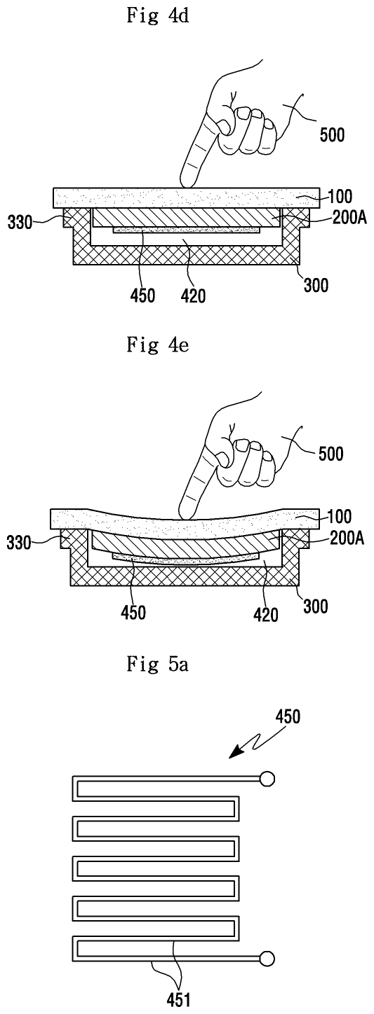

A pressure sensor layer 450 in the touch input device 1000 according to the present invention may be adhered to a lower portion of the display module 200 by an adhesive layer 300. FIG. 4a to FIG. 4e illustrate an example in which a strain gauge is applied in a touch input device according to the present invention.

In the touch input device 1000 according to the present invention, the pressure sensor layer 450 is disposed on a lower portion of the display module 200. However, the pressure sensor layer 450 may include a substrate 400, a first strain gauge 451 formed on an upper surface of the substrate 400 and a second strain gauge 452 formed on a lower surface of the substrate 400. At this time, the adhesive layer 300 may be formed between the display module 200 and the pressure sensor layer 450 to adhere the pressure sensor layer 450 to a lower portion of the display module 200.

The first strain gauge 451 and the second strain gauge 452 may be composed of an ink component, for example, a mixture including graphene. A method for depositing the first strain gauge 451 on an upper surface of the substrate 400 as an ink component, or depositing the second strain gauge 452 on a lower surface of the substrate 400 as an ink component may be a print method, an inkjet method, and the like. Here, the bigger the Young's modulus of the ink component, the more advantageous.

In the touch input device 1000 according to the present invention to which the pressure sensor layer 450 is applied, a gap between the display module 200 including the display panel 200A and the cover layer 100 having a touch sensor for detecting a touch location may be laminated with an adhesive, such as an optically clear adhesive (OCA). Accordingly, the display color clarity, visibility, and light transmittance of the display module 200 identified through a touch surface of the touch sensor may be improved.

Although the display panel 200A is illustrated as being attached to the cover layer 100 by being directly laminated in FIG. 4b and in some drawing below, this is only for convenience of description. The display module 200 in which the first polarization layers 271 and 282 are located on an upper portion of the display panel 200A may be laminated and attached to the cover layer 100, and when an LCD panel is the display panel 200A, the second polarization layer 272 and a backlight unit may be further formed.

In the description with reference to FIG. 4b to FIG. 4e, as the touch input device 1000 according to an embodiment of the present invention, the cover layer 100 on which a touch sensor is formed is illustrated as being laminated and attached with an adhesive on the display module 200 illustrated in FIG. 4a. However, the touch input device 1000 according to an embodiment of the present invention may also include a case in which the touch sensor 10 is disposed inside the display module 200 illustrated in FIG. 4a. More specifically, in FIG. 4b to FIG. 4e, the cover layer 100 on which the touch sensor is formed is illustrated as covering the display module 200 including the display panel 200A. However, the touch input device 1000 in which the touch sensor 10 is located inside the display module 200 and the display module 200 is covered with the cover layer 100 such as glass may be used as an embodiment of the present invention.

The touch input device 1000 according to an embodiment of the present invention may include an electronic device having a touch screen, the electronic device being a cell phone, a Personal Data Assistant (PDA), a smart phone, a tablet Personal Computer (PC), an MP3 player, a notebook computer, and the like.

In the touch input device 1000 according to an embodiment of the present invention, a frame substrate 330A may perform a function of covering, for example, a mounting space 310 in which a circuit board and/or a battery for the operation of the touch input device 1000 may be located, and the like together with a housing 320 which is an outermost part of the touch input device 1000. At this time, on the circuit board for the operation of the touch input device 1000, a central processing unit (CPU), which is a central processing unit, an application processor, or the like may be mounted as a main board. Through the frame substrate 330A, the display module 200 and the circuit board and/or the battery for the operation of the touch input device 1000 are separated, and electrical noise generated in the display module 200 and noise generated in the circuit board may be blocked.

In the touch input device 1000, the touch sensor 10 or the cover layer 100 may be formed wider than the display module 200, the frame substrate 330A, and the mounting space 310. Accordingly, the housing 320 may be formed such that the housing 320 surrounds the display module 200, the frame substrate 330A, and the circuit board together with the touch sensor 10.

Hereinafter, in order to be clearly distinguished from an electrode included in the touch sensor 10, a pressure sensor for detecting touch pressure is referred to as the first strain gauge 451 and the second strain gauge 452.

The touch input device 1000 according to an embodiment of the present invention may detect a touch position through the touch sensor 10 and detect touch pressure from the pressure sensor layer 450 adhered to a lower portion of the display module 200. At this time, the touch sensor 10 may be located inside or outside of the display module 200.

The touch input device 1000 according to an embodiment of the present invention may be configured to include a spacer layer 420 formed of an air gap. At this time, the spacer layer 420 may be formed of an impact absorbing material according to an embodiment. The spacer layer 420 may be filled with a dielectric material according to an embodiment.

At this time, since the pressure sensor layer 450 is disposed on a back surface of the display module 200, not on a front surface thereof, it is possible to be composed of an opaque material as well as a transparent material. When the display panel 200A included in the display module 200 is an LCD panel, light should be transmitted from a backlight unit, so that the pressure sensor layer 450 may be composed of a transparent material such as ITO.

At this time, in order to maintain the spacer layer 420, a frame 330B having a predetermined height may be formed along the edge of an upper portion of the frame substrate 330A. At this time, the frame 330B may be adhered to the cover layer 100 by an adhesive tape (not shown). In FIG. 4c, the frame 330B is illustrated as being formed in all the edges of the frame substrate 330A (for example, four sides of a quadrangular shape). However, the frame 330B may only be formed in at least some of the edges of the frame substrate 330A (for example, three sides of a quadrangular shape). According to an embodiment, the frame 330B may be integrally formed with the frame substrate 330A on an upper surface of the frame substrate 330A. In an embodiment of the present invention, the frame 330B may be composed of a material not having elasticity. In an embodiment of the present invention, when a force is applied to the display module 200 through the cover layer 100, the display module 200 may be bent together with the cover layer so that the magnitude of touch pressure may be detected even when the frame 330B is not deformed according to the force.

FIG. 4d is a cross-sectional view of a touch input device including a strain gauge according to an embodiment of the present invention. As shown in FIG. 4d, the pressure sensor layer 450 according to an embodiment of the present invention may be adhered to a lower portion of the display module 200.

FIG. 4e is a cross-sectional view when pressure is applied to the touch input device 1000 shown in FIG. 4d. An upper surface of the frame substrate 330A may have a ground potential for noise shielding. When a force is applied to a surface of the cover layer 100 through an object 500, the cover layer 100 and the display module 200 may be bent or pressed. As the display module 200 is bent, the pressure sensor layer 450 adhered to the lower portion of the display module 200 is deformed, and accordingly, the resistance values of the first strain gauge 451 and the second strain gauge 452 included in the pressure sensor layer 450 may be changed. The magnitude of the touch pressure may be calculated from the change in resistance value.

In the touch input device 1000 according to an embodiment of the present invention, the display module 200 may be bent or pressed according to a touch applying pressure. The display module 200 may be bent or pressed to indicate deformation according to the touch. According to an embodiment, a position indicating the greatest deformation when the display module 200 is bent or pressed may not match the touch location. However, the display module 200 may exhibit bending at least at the touch position. For example, when a touch position is close to the edge and the border of the display module 200, a position at which the display module 200 is bend or pressed the most may be different from the touch position. However, the display module 200 may exhibit bending or pressing at least at the touch position.

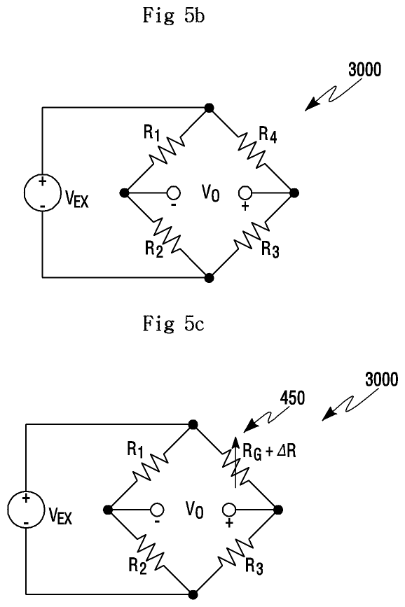

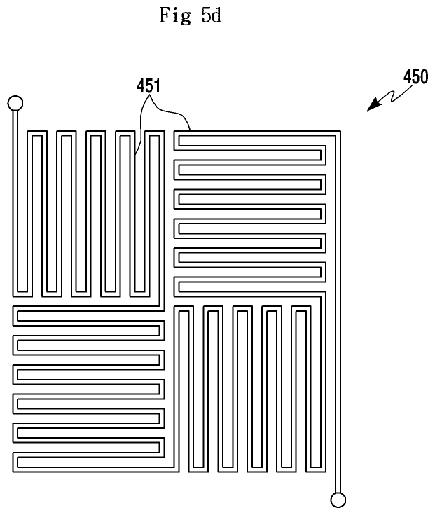

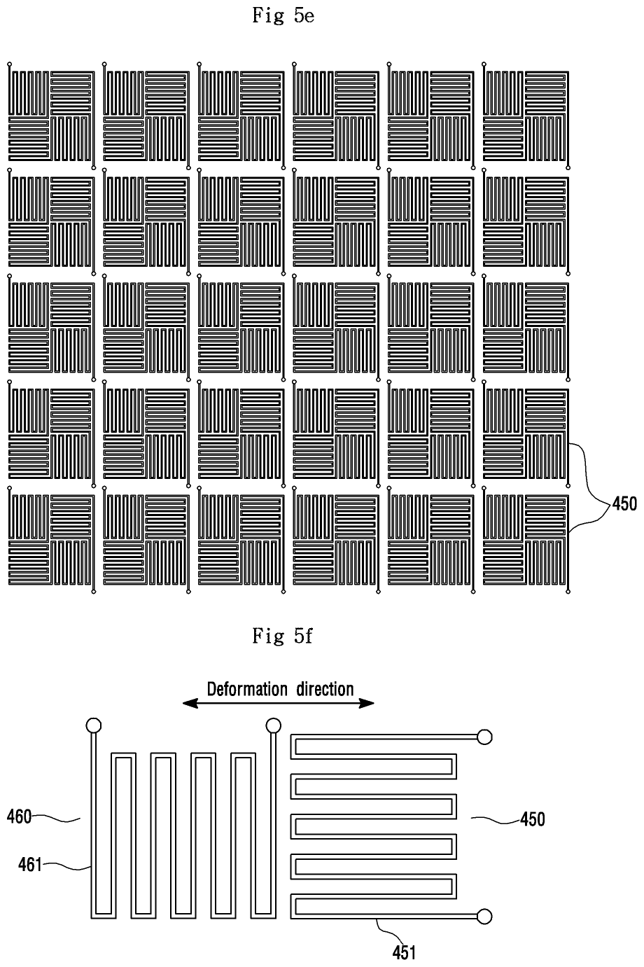

FIG. 5a and FIG. 5d to FIG. 5f are plan views of an exemplary force sensor capable of sensing touch pressure used in a touch input device according to the present invention. In this case, the force sensor may be a strain gauge. The strain gauge is a device in which electrical resistance is changed in proportion to the amount of strain, and in general, a metal-bonded strain gauge may be used.

A material which may be used in the strain gauge may include, as a transparent material, a conductive polymer polyethyleneioxythiophene (PEDOT), indium tin oxide (ITO), antimony tin oxide (ATO), carbon nanotubes (CNT), graphene, gallium zinc oxide, indium gallium zinc oxide (IGZO), tin oxide (SnO₂), indium oxide (In₂O₃), zinc oxide (ZnO), gallium oxide (Ga₂O₃), cadmium oxide (CdO), other doped metal oxides, piezoresistive elements, piezoresistive semiconductor materials, piezoresistive metal materials, silver nanowires, platinum nanowires, nickel nanowires, other metallic nanowires, and the like. As an opaque material, silver ink, copper, nano silver, carbon nanotubes (CNT), Constantan alloys, Karma alloys, doped polycrystalline silicon, doped amorphous silicon, doped single crystal silicon, other doped semiconductor materials, and the like may be used.

As shown in FIG. 5a, a metal strain gauge may be composed of metal foils arranged in a lattice manner. The lattice manner may maximize the amount of deformation of a metal wire or foil which may be easily deformed in a parallel direction. At this time, a vertical lattice cross-section of the first strain gauge 451 shown in FIG. 5a may be minimized to reduce the effect of shear strain and Poisson strain. Hereinafter, since the shape of the first strain gauge 451 and the shape of the second strain gauge 452 may be substantially the same, a description will be given with respect to the first strain gauge 451, and the same description may be applied to the second strain gauge 452.

In the example of FIG. 5a, the first strain gauge 451 may include traces which are not in contact but disposed close to each other while being in an at rest state, that is, while not being strained or otherwise deformed. The strain gauge may have a nominal resistance, such as 1.8 KΩ±0.1%, in the absence of a strain or a force. As a basic parameter of the strain gauge, the sensitivity to strain may be expressed as a gauge coefficient (GF). At this time, the gauge coefficient may be defined as a ratio of the change in electrical resistance to the change in length (strain) and may be expressed as a function of a strain ε as follows.

$$GF = \frac{Δ R \text{/} R}{Δ L \text{/} L} = \frac{Δ R \text{/} R}{ɛ}$$

Here, ΔR is the amount of change in strain gauge resistance, R is the resistance of an undeformed strain gauge, and GF is a gauge coefficient.

At this time, in order to measure a small change in resistance, the strain gauge is used in a bridge setting having a voltage driving source in most cases. FIG. 5b and FIG. 5c illustrate an exemplary strain gauge which may be applied to a touch input device according to the present invention. As shown in the example of FIG. 5b, the strain gauge is included in a Wheatstone bridge 3000 having four different resistors (shown as R1, R2, R3, and R4) to sense the change in resistance of a gauge indicating an applied force (for other resistors). The bridge 3000 is coupled to a force sensor interface (not shown) and receives a driving signal (voltage V_{EX}) from a touch controller (not shown) to drive the strain gauge, and may transmit a sensing signal (voltage Vₒ) indicating a force applied for processing to a touch controller. At this time, an output voltage Vₒ of the bridge 3000 may be represented as follows.

$${V}_{0} = [ \frac{{R}_{3}}{{R}_{3} + {R}_{4}} - \frac{{R}_{2}}{{R}_{1} + {R}_{2}} ] \cdot {V}_{EX}$$

In the above equation, when R1/R2=R4/R3, the output voltage Vₒ becomes 0. Under the above condition, the bridge 3000 is in a balanced state. At this time, if the resistance value of any one of the resistors included in the bridge 300 is changed, the output voltage Vₒ, which is not zero, is output.

At this time, as shown in FIG. 5c, when the first strain gauge 451 is R_{G} and the R_{G} is changed, the change in resistance of the first strain gauge 451 results in an imbalance in the bridge and generates the output voltage Vₒ which is not zero. When the nominal resistance of the first strain gauge 451 is R_{G}, the change ΔR in resistance induced by deformation may be represented by ΔR=R_{G}×GF×ε through the above gauge coefficient equation. At this time, when assuming R1=R2 and R3=R_{G}, the above bridge equation may be rewritten as a function for the strain ε of Vₒ/V_{EX} as follows.

$$\frac{{V}_{0}}{{V}_{EX}} = - \frac{GF \cdot ɛ}{4} ( \frac{1}{1 + GF \cdot \frac{ɛ}{2}} )$$

Although the bridge of FIG. 5c includes only one first strain gauge 451, up to four strain gauges may be used at positions illustrated by R1, R2, R3, and R4 included in the bridge of FIG. 5b, and in this case, it will be understood that the resistance change of the gauges may be used to sense an applied force.

As shown in FIG. 4d and FIG. 4e, when touch pressure is applied to the display module 200 to which the pressure sensor layer 450 is adhered, the display module 200 is bent and as the display module is bent, the resistance of the first strain gauge 451 formed on an upper surface of the substrate 400 is decreased and the resistance of the second strain gauge 452 formed on a lower surface of the substrate 400 is increased. As the touch pressure applied increases, the resistance of the first strain gauge 451 and the resistance of the second strain gauge 452 may correspondingly change (that is, the resistance may decrease or increase). Therefore, when the force sensor controller 1300 detects an amount of change in resistance value of the first strain gauge 451 and the second strain gauge 452, the amount of change in resistance value may be interpreted as the touch pressure applied to the display module 200.

In another embodiment, the bridge 3000 may be integrated with the force sensor controller 1300, and in this case, at least one of the resistors R1, R2, and R3 may be replaced with a resistor in the force sensor controller 1300. For example, resistors R2 and R3 may be replaced by resistors in the force sensor controller 1300 and the bridge 300 may be formed with the first strain gauge 451 and a resistor R1. Accordingly, a space occupied by the bridge 3000 may be reduced.

Since the traces of the first strain gauge 451 illustrated in FIG. 5a is arranged in the horizontal direction, the change in length of the traces to deformation in the horizontal direction is large so that the sensitivity to the deformation in the horizontal direction is high. However, since the change in length of the traces to deformation in the vertical direction is relatively small, the sensitivity to the deformation in the vertical direction is low. As shown in FIG. 5d, the first strain gauge 451 includes a plurality of detailed regions, and it is possible to configure the arrangement direction of traces included in each of the detailed regions differently. By configuring the first strain gauge 451 including traces having different arrangement directions, the sensitivity difference of the first strain gauge 451 to the deformation direction may be reduced.

The touch input device 1000 according to the present invention may be provided with a force sensor composed of a single channel by forming one first strain gauge 451 on a lower portion of the display module 200 as shown in FIG. 5a and FIG. 5d. In addition, the touch input device 1000 according to the present invention may be provided with a force sensor composed of a plurality of channels by forming the plurality of first strain gauge 451 in plurality on a lower portion of the display module 200 as shown in FIG. 5e. By using the force sensor composed of the plurality of channels, the magnitude of each of a plurality of forces for a plurality of touches may be simultaneously sensed.

An increase in temperature causes the display module 200 to expand even without applied touch pressure, and as a result, the pressure sensor layer 450 formed on a lower portion of the display module 200 may be stretched, so that a temperature change may adversely affect the pressure sensor layer 450. As a result, the resistance of the first strain gauge 451 included in the pressure sensor layer 450 is increased and may be erroneously interpreted as touch pressure applied to the first strain gauge 451.

To compensate for the temperature change, at least one of the resistors R1, R2, and R3 of the bridge 3000 illustrated in FIG. Sc may be replaced with a thermistor. The resistance change due to the temperature of the thermistor may correspond to the resistance change due to the temperature of the first strain gauge 451 caused by the thermal expansion of the display module 200, so that the change in the output voltage Vₒ due to temperature may be reduced.

In addition, the effect of temperature change may be minimized by using two gauges. For example, as shown in FIG. 5f, when deformation in the horizontal direction occurs, traces of the first strain gauges 451 may be arranged in a horizontal direction parallel to a deformation direction, and traces of a dummy gauge 461 may be arranged in a vertical direction perpendicular to the deformation direction. At this time, the deformation affects the first strain gauge 451 and hardly affects the dummy gauge 461. However, the temperature affects both the first strain gauge 451 and the dummy gauge 461. Accordingly, since the temperature change is equally applied to the two gauges, the ratio of the nominal resistance RG of the two gauges does not change. At this time, when the two gauges share an output node of the Wheatstone bridge, that is, when the two gauges are R1 and R2 of FIGS. 5b, or R3 and R4, the output voltage Vₒ of the bridge 3000 also does not change, so that the effect of the temperature change may be minimized.

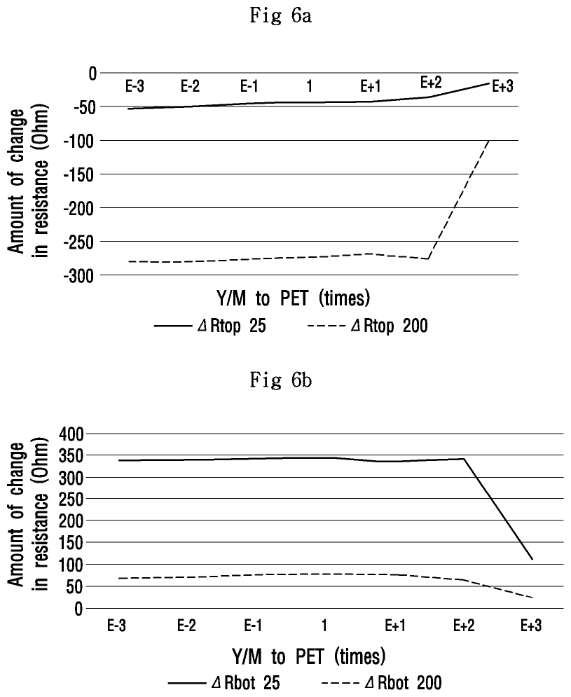

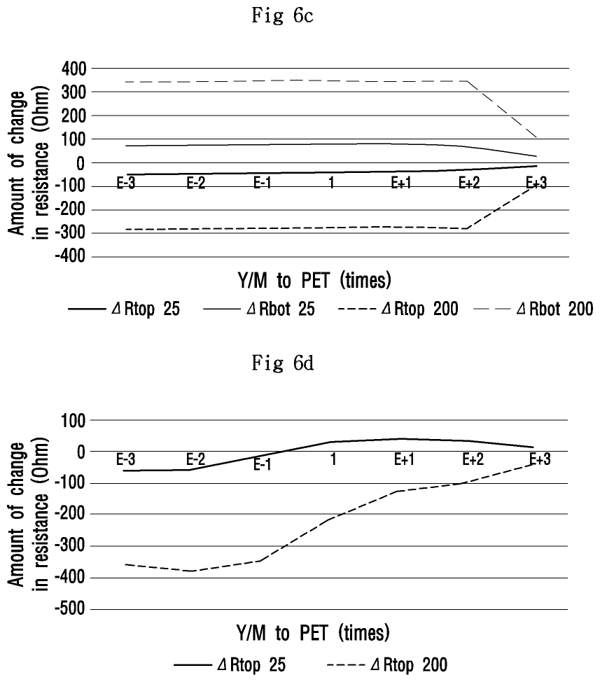

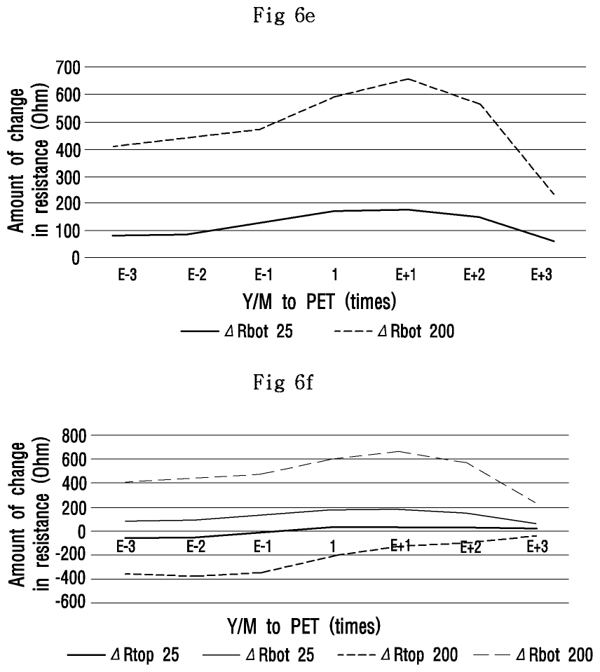

Hereinafter, referring to FIG. 4a and FIG. 6a to FIG. 6f, the technical spirit of the present invention and simulation results regarding the same will be described.

Referring to FIG. 4a, the touch input device 1000 according to an embodiment of the present invention includes the display module 200 and the pressure sensor layer 450 disposed on a lower portion of the display module 200, and the adhesive layer 300 is present between the display module 200 and the pressure sensor layer 300 to adhere the pressure sensor layer 450 to the display module 200.

The pressure sensor layer 450 may include a structure in which the first strain gauge 451 is formed on an upper surface of the substrate 400 and the second strain gauge 452 is formed on a lower surface of the substrate 400. At this time, the first strain gauge 451 and the second strain gauge 452 may be formed at positions corresponding to each other on the opposite sides of the substrate 400. According to an embodiment, the first strain gauge 451 may be formed in plurality on an upper surface of the substrate 400 and the second strain gauge 452 may be formed in plurality on a lower surface of the substrate 400. In addition, the first strain gauge 451 and the second strain gauge 452 formed at positions corresponding to each other in the substrate 400 may be electrically connected.

In the touch input device 1000 according to an embodiment of the present invention, when pressure is applied to the display module 200, the display module 200 is bent, and as the display module 200 is bent, the electrical properties (for example, a resistance value) of each of the first strain gauge 451 and the second strain gauge 452 are changed. At this time, the Young's Modulus of the substrate 400 may be greater than the Young's Modulus of the adhesive layer 3000 and may be less than 500 GPa.

The technical spirit according to the present invention is a result verified according to the simulation results. When the Young's Modulus of the substrate 400 is equal to or less than the Young's Modulus of the adhesive layer 300, the sensitivity for detecting touch pressure is significantly low. When the Young's Modulus of the substrate 400 is greater than the Young's Modulus of the adhesive layer 300, the sensitivity for detecting touch pressure is increased and the sensitivity for detecting touch pressure is gradually reduced at 500 GPa or greater.

Referring to FIG. 6a to FIG. 6c, results of a simulation performed while varying the Young's Modulus of the glass layer 200B included in the display module 200 are shown. Here, it is assumed that the substrate 400 is PET and that the Young's Modulus of the adhesive layer 300 is 1/10,000 of the Young's Modulus of the substrate 400. The x-axis of the graph represents the ratio of the Young's Modulus of the glass layer 200B to the Young's Modulus of the substrate 400. For example, E+1 means 10 times, E+2 means 100 times, E−1 means 1/10 times, and E−2 means 1/100 times. A solid line is a case in which the thickness of the substrate 400 is 25 μm, and a dotted line is a simulation result of a case in which the thickness of the substrate 400 is 200 μm. A portion marked top is a simulation result for the first strain gauge 451, and a portion marked bot is a simulation result for the second strain gauge 452. When the simulation results of the first strain gauge 451 and the second strain gauge 452 are combined and analyzed as one, unless the Young's Modulus of the glass layer 200B is more than 100 times the Young's Modulus of the substrate 400, the detection sensitivity to touch pressure is not affected. That is, it can be seen that the amount of change in resistance is almost constant before E+2. In addition, it can be seen that the thicker the thickness of the substrate 400, the greater the absolute value of the amount of change in resistance, which means that the detection sensitivity to touch pressure is great.

Referring to FIG. 6d to FIG. 6f, results of a simulation performed while varying the Young's Modulus of the glass layer 200B included in the display module 200 are shown. Here, it is also assumed that the substrate 400 is PET and that the Young's Modulus of the adhesive layer 300 is 1/100 of the Young's Modulus of the substrate 400 (different from the simulation in FIG. 6a to FIG. 6c). The x-axis of the graph represents the ratio of the Young's Modulus of the glass layer 200B to the Young's Modulus of the substrate 400. For example, E+1 means 10 times, E+2 means 100 times, E−1 means 1/10 times, and E−2 means 1/100 times. A solid line is a case in which the thickness of the substrate 400 is 25 μm, and a dotted line is a simulation result of a case in which the thickness of the substrate 400 is 200 μm. A portion marked top is a simulation result for the first strain gauge 451, and a portion marked bot is a simulation result for the second strain gauge 452. When the simulation results of the first strain gauge 451 and the second strain gauge 452 are combined and analyzed as one, the thicker the thickness of the substrate 400, the greater the absolute value of the amount of change in resistance, which means that the detection sensitivity to touch pressure is great. In addition, it can be seen that only when the Young's Modulus of the glass layer 200B is lower than the Young's Modulus of the substrate 400 (that is, orientation toward a (+) direction and a (−) direction becomes more pronounced toward E−3), the first strain gauge 451 and the second strain gauge 452 may secure orientation.

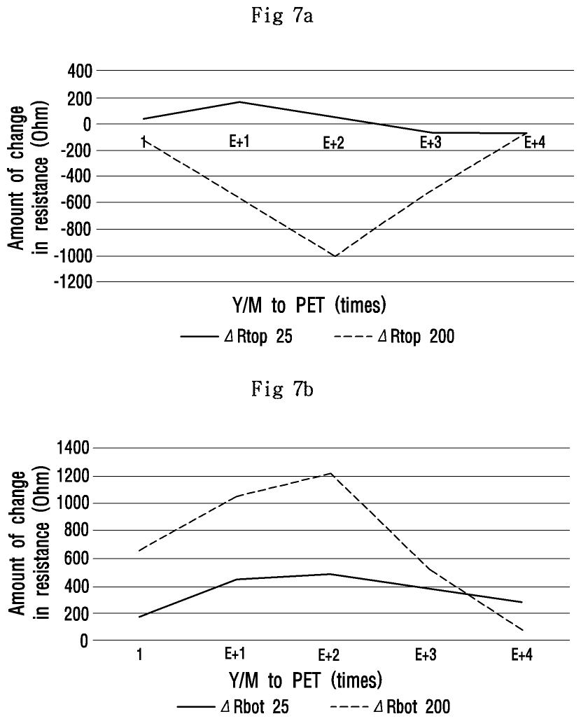

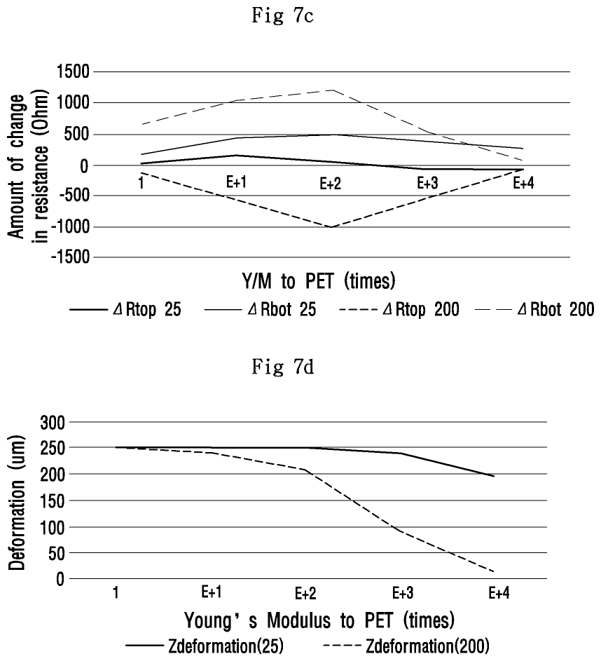

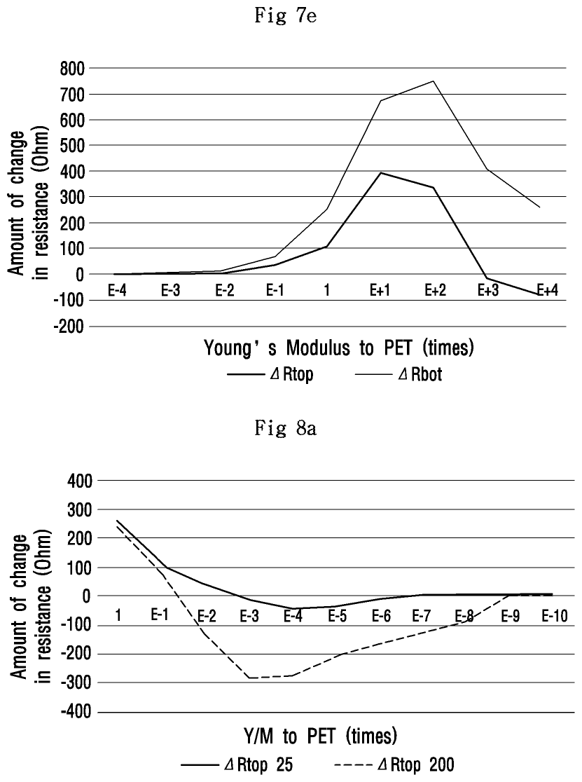

Referring to FIG. 7a to FIG. 7d, results of a simulation performed while varying the Young's Modulus of the substrate 400 included in the pressure sensor layer 450 are shown. Here, it is assumed that the Young's Modulus of the glass layer 200B is 10 times the Young's Modulus of PET and that the Young's Modulus of the adhesive layer 300 is 1/100 of that of PET. The x-axis of the graph represents the ratio of the Young's Modulus of the substrate 400 to the Young's Modulus of PET. For example, E+1 means 10 times, E+2 means 100 times, E−1 means 1/10 times, and E−2 means 1/100 times. A solid line is a case in which the thickness of the substrate 400 is 25 μm, and a dotted line is a simulation result of a case in which the thickness of the substrate 400 is 200 μm. A portion marked top is a simulation result for the first strain gauge 451, and a portion marked bot is a simulation result for the second strain gauge 452. When the simulation results of the first strain gauge 451 and the second strain gauge 452 are combined and analyzed as one, since it can be seen that Z displacement is decreased after E+2 (see FIG. 7d), when the substrate 400 is too hard (for example, the Young's Modulus of the substrate 400 is more than 100 times higher than that of PET), it can be analyzed that the detection sensitivity to touch pressure is poor and the substrate 400 is too hard to be pressed. Therefore, when the substrate 400 is too hard, the detection sensitivity to touch pressure is adversely affected.

Referring to FIG. 7e, results of a simulation performed while varying the Young's Modulus of the substrate 400 included in the pressure sensor layer 450 are shown. Here, it is assumed that the Young's Modulus of the glass layer 200B is 10 times the Young's Modulus of PET and that the Young's Modulus of the adhesive layer 300 is 1/10 of that of PET (different from the simulation in FIG. 7a to FIG. 7d). The x-axis of the graph represents the ratio of the Young's Modulus of the substrate 400 to the Young's Modulus of PET. For example, E+1 means 10 times, E+2 means 100 times, E−1 means 1/10 times, and E−2 means 1/100 times. The simulation result of FIG. 7e is shown for a case in which where the thickness of the substrate is 25 μm. A portion marked top is a simulation result for the first strain gauge 451, and a portion marked bot is a simulation result for the second strain gauge 452. When the simulation results of the first strain gauge 451 and the second strain gauge 452 are combined and analyzed as one, when the Young's Modulus of the substrate 400 is 1/10 of or less than the Young's Modulus of PET, it can be seen that the detection sensitivity to touch pressure converges to almost zero. Therefore, referring to FIG. 7e, it can be seen that the detection sensitivity to touch pressure is present only when the Young's Modulus of the substrate 400 is greater than the Young's Modulus of the adhesive layer 300.

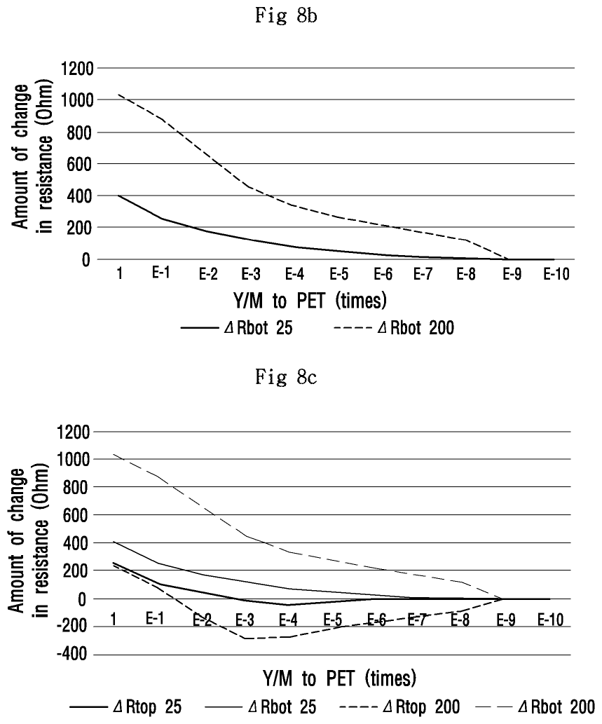

Referring to FIG. 8a to FIG. 8c, results of a simulation performed while varying the Young's Modulus of the adhesive layer 300 are shown. Here, it is assumed that the Young's Modulus of the glass layer 200B is 10 times the Young's Modulus of PET and that the substrate 400 is PET. The x-axis of the graph represents the ratio of the Young's Modulus of the adhesive layer 300 to the Young's Modulus of PET. For example, E+1 means 10 times, E+2 means 100 times, E−1 means 1/10 times, and E−2 means 1/100 times. A solid line is a case in which the thickness of the substrate 400 is 25 μm, and a dotted line is a simulation result of a case in which the thickness of the substrate 400 is 200 μm. A portion marked top is a simulation result for the first strain gauge 451, and a portion marked bot is a simulation result for the second strain gauge 452. When the simulation results of the first strain gauge 451 and the second strain gauge 452 are combined and analyzed as one, the thicker the thickness of the substrate 400, the greater the absolute value of the amount of change in resistance, which means that the detection sensitivity to touch pressure is great. When the Young's Modulus of the adhesive layer 300 becomes smaller so that the Young's Modulus of the adhesive layer 300 is smaller than the case of E−3, it can be seen that there is a change in orientation of the first strain gauge 451 and the second strain gauge 452.

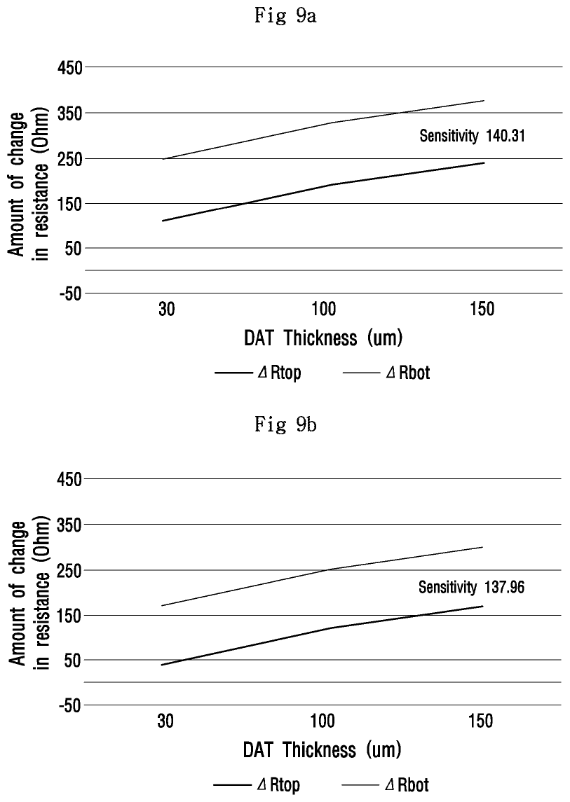

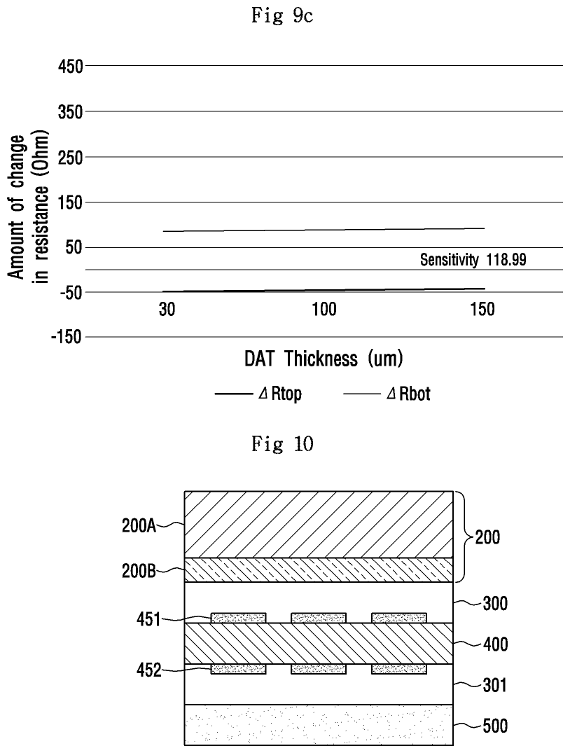

Referring to FIG. 9a to FIG. 9c, results of simulation performed while varying the Young's Modulus of the adhesive layer 300 are shown. In FIG. 9a, results of a simulation performed while varying the thickness of the adhesive layer 300 when the Young's Modulus of the adhesive layer 300 is 1/10 of that of PET are shown. In FIG. 9b, results of a simulation performed while varying the thickness of the adhesive layer 300 when the Young's Modulus of the adhesive layer 300 is 1/100 of that of PET are shown. In FIG. 9c, results of a simulation performed while varying the thickness of the adhesive layer 300 when the Young's Modulus of the adhesive layer 300 is 1/10,000 of that of PET are shown. Referring to FIG. 9a to FIG. 9c, it can be seen that the touch pressure detection sensitivity is substantially the same regardless of the thickness of the adhesive layer 300. When the results are analyzed, it can be said that the adhesive layer 300 is more affected by the Young's modulus than by thickness.

FIG. 10 is a cross-sectional view schematically illustrating a portion of a touch input device according to another embodiment of the present invention.

Referring to FIG. 10, the touch input device 1000 according to another embodiment of the present invention includes the display module 200 and the pressure sensor layer 450 disposed on a lower portion of the display module 200, and a first adhesive layer 300 is present between the display module 200 and the pressure sensor layer 450 to adhere the pressure sensor layer 450 to the display module 200.

In addition, a material layer for substrate reinforcement 500 is disposed on a lower portion of the pressure sensor layer 450, and a second adhesive layer 301 is present between the pressure sensor layer 450 and the material layer for substrate reinforcement 500 to adhere the pressure sensor layer 450 and the material layer for substrate reinforcement 500. The material layer for substrate reinforcement 500 may be formed of a material, for example, stainless steel (SUS), rubber, and the like.

The pressure sensor layer 450 may include a structure in which the first strain gauge 451 is formed on an upper surface of the substrate 400 and the second strain gauge 452 is formed on a lower surface of the substrate 400. At this time, the first strain gauge 451 and the second strain gauge 452 may be formed at positions corresponding to each other on the opposite sides of the substrate 400. According to an embodiment, the first strain gauge 451 may be formed in plurality on an upper surface of the substrate 400 and the second strain gauge 452 may be formed in plurality on a lower surface of the substrate 400. In addition, the first strain gauge 451 and the second strain gauge 452 formed at positions corresponding to each other in the substrate 400 may be electrically connected.

The first adhesive layer 300 and the second adhesive layer 301 may be formed of the same material, but the Young's Modulus of the first adhesive layer 300 may be smaller than the Young's Modulus of the second adhesive layer 301.

In the touch input device 1000 according to an embodiment of the present invention, when pressure is applied to the display module 200, the display module 200 is bent, and as the display module 200 is bent, the electrical properties (for example, a resistance value) of each of the first strain gauge 451 and the second strain gauge 452 are changed. At this time, the Young's Modulus of the substrate 400 may be greater than the Young's Modulus of the adhesive layer 3000 and may be less than 500 GPa.

The technical spirit according to the present invention is a result verified according to the simulation results. When the Young's Modulus of the substrate 400 is equal to or less than the Young's Modulus of the adhesive layer 300, the sensitivity for detecting touch pressure is significantly low. When the Young's Modulus of the substrate 400 is greater than the Young's Modulus of the adhesive layer 300, the sensitivity for detecting touch pressure is increased and the sensitivity for detecting touch pressure is gradually reduced at 500 GPa or greater.

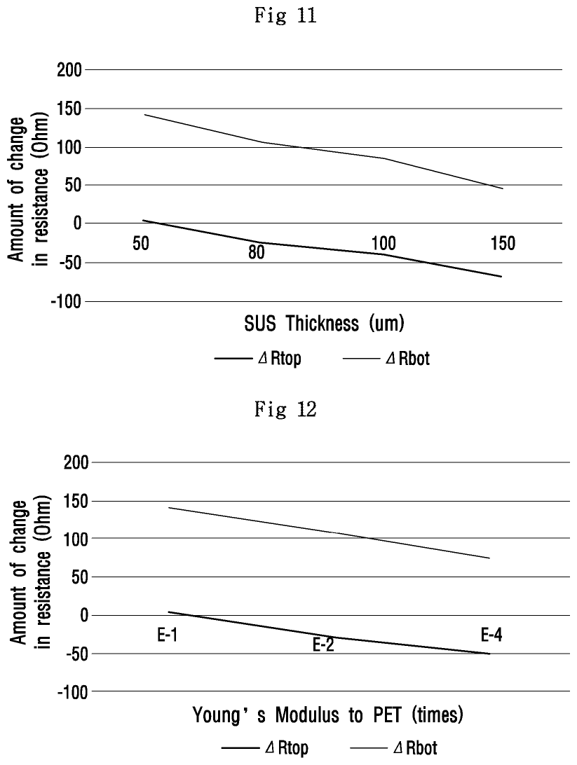

Referring to FIG. 11, results of a simulation performed while varying the thickness of the material layer for substrate reinforcement 500 are shown. The x-axis of the graph represents the thickness of the material layer for substrate reinforcement 500. When analyzed with reference to FIG. 11, it can be seen that the detection sensitivity to touch pressure is not affected even when the material layer for substrate reinforcement 500 is changed.

Referring to FIG. 12, assuming that the first adhesive layer 300 and the second adhesive layer 301 are formed of the same material, results of a simulation performed while varying the Young's Modulus of the first adhesive layer 300 and the Young's Modulus of the second adhesive layer 301 are changed together are shown. The x-axis of the graph represents the ratio of the Young's Modulus of the first adhesive layer 300 or that of the second adhesive layer 301 to the Young's Modulus of PET. For example, E+1 means 10 times, E+2 means 100 times, E−1 means 1/10 times, and E−2 means 1/100 times. When analyzed with reference to FIG. 12, it can be seen that the detection sensitivity to touch pressure is not affected by the Young's Modulus of an adhesive layer (that is, the second adhesive layer 301) of a surface to which the material layer for substrate reinforcement 500 is attached.

Hereinafter, results of a simulation performed under the assumption that the Young's Modulus of the first adhesive layer 300 and that of the second adhesive layer 301 are different from each other will be described.

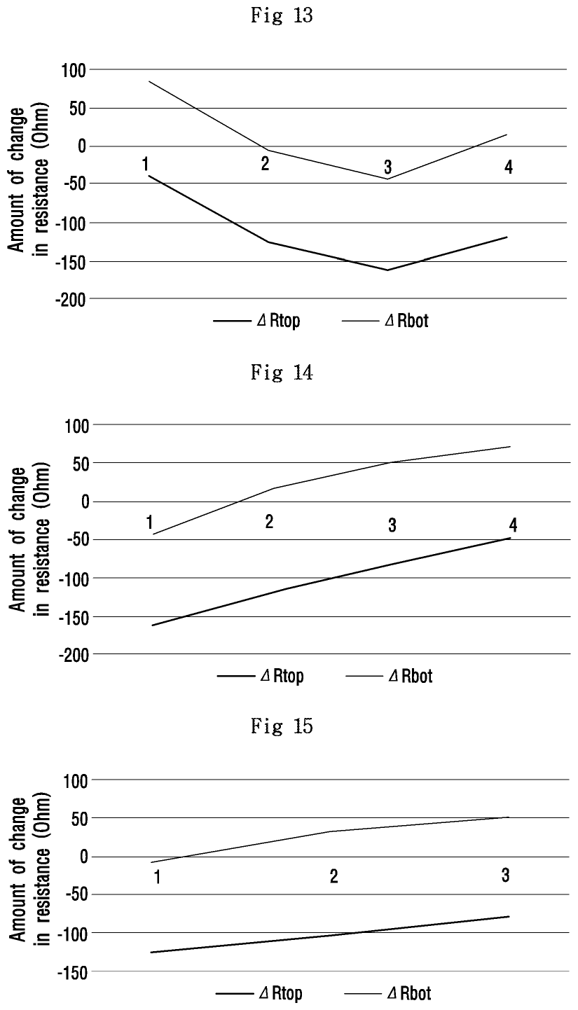

Referring to FIG. 13, in Case 1, the Young's Modulus of the first adhesive layer 300 is 1/10 of the Young's Modulus of PET, and the Young's Modulus of the second adhesive layer 301 is 1/10 of the Young's modulus of PET. At this time, the detection sensitivity to touch pressure is 125.0107.

In Case 2, the Young's Modulus of the first adhesive layer 300 is 1/100 of the Young's Modulus of PET, and the Young's Modulus of the second adhesive layer 301 is 1/10 of the Young's Modulus of PET. At this time, the detection sensitivity to touch pressure is 121.2163.

In Case 3, the Young's Modulus of the first adhesive layer 300 is 1/10,000 of the Young's Modulus of PET, and the Young's Modulus of the second adhesive layer 301 is 1/10 of the Young's Modulus of PET. At this time, the detection sensitivity to touch pressure is 118.9174.

In Case 4, the Young's Modulus of the first adhesive layer 300 is 1/10,000 of the Young's Modulus of PET, and the Young's Modulus of the second adhesive layer 301 is 1/100 of the Young's Modulus of PET. At this time, the detection sensitivity to touch pressure is 135.4304.

When analyzed with reference to FIG. 13, it can be seen that when the Young's Modulus of the first adhesive layer 300 is smaller than the Young's Modulus of the second adhesive layer 301, it is advantageous in terms of detection sensitivity to touch pressure or securing orientation.

Referring to FIG. 14, in Case 1, the Young's Modulus of the first adhesive layer 300 is 1/10,000 of the Young's Modulus of PET, and the Young's Modulus of the second adhesive layer 301 is 1/10 of the Young's modulus of PET. At this time, the detection sensitivity to touch pressure is 118.92.

In Case 2, the Young's Modulus of the first adhesive layer 300 is 1/10,000 of the Young's Modulus of PET, and the Young's Modulus of the second adhesive layer 301 is 1/100 of the Young's Modulus of PET. At this time, the detection sensitivity to touch pressure is 135.43.

In Case 3, the Young's Modulus of the first adhesive layer 300 is 1/10,000 of the Young's Modulus of PET, and the Young's Modulus of the second adhesive layer 301 is 1/1,000 of the Young's Modulus of PET. At this time, the detection sensitivity to touch pressure is 132.82.

In Case 4, the Young's Modulus of the first adhesive layer 300 is 1/10,000 of the Young's Modulus of PET, and the Young's Modulus of the second adhesive layer 301 is 1/10,000 of the Young's Modulus of PET. At this time, the detection sensitivity to touch pressure is 121.98.

When analyzed with reference to FIG. 14, when the Young's Modulus of the first adhesive layer 300 is smaller than the Young's Modulus of the second adhesive layer 301 (preferably, the Young's Modulus of the first adhesive layer 300 is about 1/100 of the Young's Modulus of the second adhesive layer 301), it is advantageous in terms of detection sensitivity to touch pressure or securing orientation.

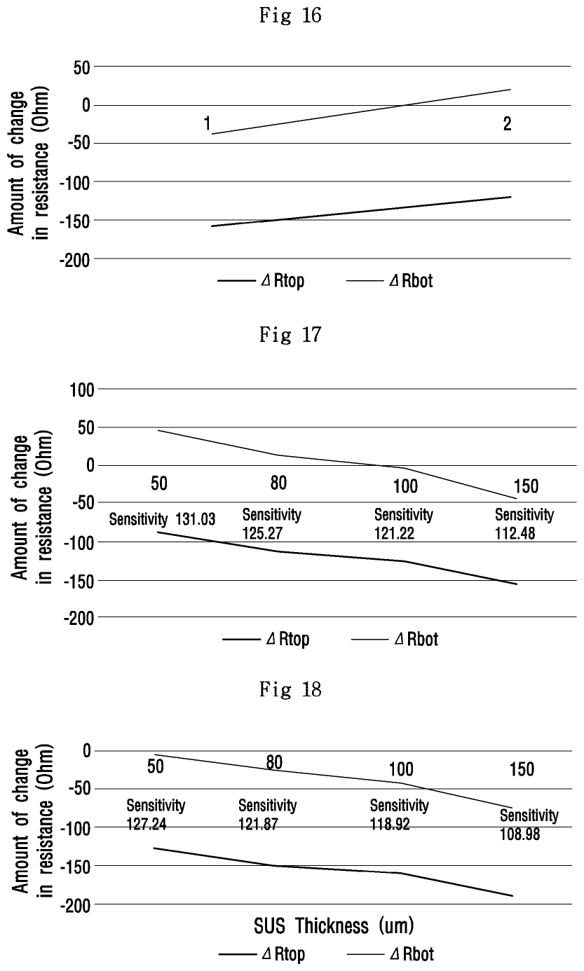

FIGS. 15 and 16 are graphs showing results of a simulation performed when the ratio of Young's Modulus between a first adhesive layer and a second adhesive layer is fixed.

Referring to FIG. 15, in Case 1, the Young's Modulus of the first adhesive layer 300 is 1/100 of the Young's Modulus of PET, and the Young's Modulus of the second adhesive layer 301 is 1/10 of the Young's Modulus of PET. At this time, the detection sensitivity to touch pressure is 121.2163.

In Case 2, the Young's Modulus of the first adhesive layer 300 is 1/1,000 of the Young's Modulus of PET, and the Young's Modulus of the second adhesive layer 301 is 1/100 of the Young's Modulus of PET. At this time, the detection sensitivity to touch pressure is 135.5150.

In Case 3, the Young's Modulus of the first adhesive layer 300 is 1/10,000 of the Young's Modulus of PET, and the Young's Modulus of the second adhesive layer 301 is 1/1,000 of the Young's Modulus of PET. At this time, the detection sensitivity to touch pressure is 132.8164.

Referring to FIG. 16, in Case 1, the Young's Modulus of the first adhesive layer 300 is 1/1,000 of the Young's Modulus of PET, and the Young's Modulus of the second adhesive layer 301 is 1/10 of the Young's Modulus of PET. At this time, the detection sensitivity to touch pressure is 120.1588.

In Case 2, the Young's Modulus of the first adhesive layer 300 is 1/10,000 of the Young's Modulus of PET, and the Young's Modulus of the second adhesive layer 301 is 1/100 of the Young's modulus of PET. At this time, the detection sensitivity to touch pressure is 135.4304.

When analyzed with reference to FIG. 15 and FIG. 16, it can be seen that the detection sensitivity to touch pressure is more affected by the Young's Modulus of the second adhesive layer 301.

FIGS. 17 and 18 are graphs showing results of a simulation performed while varying the thickness of a material layer for substrate reinforcement.

Referring to FIG. 17, the Young's Modulus of the first adhesive layer 300 is 1/100 of the Young's Modulus of PET, and the Young's Modulus of the second adhesive layer 301 is 1/10 of the Young's Modulus of PET. At this time, when the thickness of the material layer for substrate reinforcement 500 is changed, that is, when the thickness of the material layer for substrate reinforcement 500 is 50 μm, the detection sensitivity to touch pressure is 131.03, and when the thickness of the material layer for the substrate reinforcement 500 is 80 μm, the detection sensitivity to touch pressure is 125.27. When the thickness of the material layer for substrate reinforcement 500 is 100 μm, the detection sensitivity to touch pressure is 121.21, and when the thickness of the material layer for substrate reinforcement 500 is 150 μm, the detection sensitivity to touch pressure is 112.48.

Referring to FIG. 18, the Young's Modulus of the first adhesive layer 300 is 1/10,000 of the Young's Modulus of PET, and the Young's Modulus of the second adhesive layer 301 is 1/10 of the Young's Modulus of PET. At this time, when the thickness of the material layer for substrate reinforcement 500 is changed, that is, when the thickness of the material layer for substrate reinforcement 500 is 50 μm, the detection sensitivity to touch pressure is 127.24, and when the thickness of the material layer for the substrate reinforcement 500 is 80 μm, the detection sensitivity to touch pressure is 121.87. When the thickness of the material layer for substrate reinforcement 500 is 100 μm, the detection sensitivity to touch pressure is 118.92, and when the thickness of the material layer for substrate reinforcement 500 is 150 μm, the detection sensitivity to touch pressure is 108.98.

When analyzed with reference to FIG. 17 and FIG. 18, it can be seen that as the thickness of the material layer for substrate reinforcement 500 increases, the detection sensitivity to touch pressure decreases and Z displacement decreases (that is, the difference in Z displacement is 10 μm at 50 μm/150 μm). When the Young's Modulus of the first adhesive layer 300 and that of the second adhesive layer 301 are different from each other to be used, whether or not it is possible to secure orientation will vary depending on a case.

The features, structures, effects, and the like described in the above embodiments are included in one embodiment of the present invention, but are not necessarily limited to the one embodiment. Furthermore, the features, structures, effects, and the like illustrated in each embodiment may be combined or modified in other embodiments and implemented by those skilled in the art to which the embodiments belong. Therefore, it should be interpreted that the contents related to such a combination and modification are included in the scope of the present invention

In addition, the above description has been made with reference to an embodiment, but it is merely illustrative and does not limit the present invention. It will be understood by those skilled in the art that various modifications and applications not illustrated above are possible without departing from the essential characteristics of the present embodiment. For example, each component specifically shown in the embodiment may be modified and implemented. Differences related to such a modification and application should be construed as being included in the scope of the invention defined in the appended claims.

### INDUSTRIAL APPLICABILITY

According to a touch input device using a pressure sensor layer including a strain gauge according to the above configuration, the detection sensitivity to touch pressure may be improved.

Also, there is an advantage in that it is advantageous to ensure the orientation of each strain gauge formed on the opposite sides of a substrate of the pressure sensor layer.

1. A touch input device capable of detecting touch pressure, comprising:
a display module; and
a pressure sensor layer disposed on a lower portion of the display module, wherein
an adhesive layer is present between the display module and the pressure sensor layer to adhere the pressure sensor layer to the display module,
the pressure sensor layer includes a structure in which a first strain gauge is formed on an upper surface of a substrate and a second strain gauge is formed on a lower surface of the substrate,
when pressure is applied to the display module, the display module is bent,
the electrical properties of each of the first strain gauge and the second strain gauge are changed as the display module is bent, and
the Young's Modulus of the substrate is greater than the Young's Modulus of the adhesive layer.

2. The touch input device of claim 1, wherein the Young's Modulus of the substrate is less than 500 GPa.

3. The touch input device of claim 1, wherein the first strain gauge and the second strain gauge are formed at positions corresponding to each other on the opposite sides of the substrate.

4. The touch input device of claim 3, wherein the first strain gauge is formed in plurality on the upper surface of the substrate and the second strain gauge is formed in plurality on the lower surface of the substrate.

5. The touch input device of claim 3, wherein the first strain gauge and the second strain gauge formed at positions corresponding to each other of the substrate are electrically connected.

6. A touch input device capable of detecting touch pressure, comprising:
a display module;
a pressure sensor layer disposed on a lower portion of the display module and including a substrate, a first strain gauge formed on an upper surface of the substrate, and a second strain gauge formed on a lower surface of the substrate;
a first adhesive layer formed between the display module and the pressure sensor layer to adhere the display module and the pressure sensor layer;
a material layer for substrate reinforcement disposed on a lower portion of the pressure sensor layer; and
a second adhesive layer formed between the pressure sensor layer and the material layer for substrate reinforcement to adhere the pressure sensor layer and the material layer for substrate reinforcement, wherein
when pressure is applied to the display module, the display module is bent,
the electrical properties of each of the first strain gauge and the second strain gauge are changed as the display module is bent, and
the Young's Modulus of the substrate is greater than the Young's Modulus of the first adhesive layer and the Young's Modulus of the second adhesive layer. The touch input device of claim 6, wherein the Young's Modulus of the substrate is less than 500 GPa.

8. The touch input device of claim 6, wherein the first adhesive layer and the second adhesive layer are formed of the same material.

9. The touch input device of claim 6, wherein the Young's Modulus of the first adhesive layer is less than the Young's Modulus of the second adhesive layer.

10. The touch input device of claim 6, wherein the first strain gauge and the second strain gauge are formed at positions corresponding to each other on the opposite sides of the substrate.

11. The touch input device of claim 10, wherein the first strain gauge is formed in plurality on an upper surface of the substrate and the second strain gauge is formed in plurality on a lower surface of the substrate.

12. The touch input device of claim 10, wherein the first strain gauge and the second strain gauge formed at positions corresponding to each other of the substrate are electrically connected.
